(19) United States
(12) Patent Application Publication
(10) Pub. No.: US 2009/0283922 A1
(43) Pub. Date: Nov. 19, 2009

(54) INTEGRATING HIGH STRESS CAP LAYER IN HIGH-K METAL GATE TRANSISTOR

(76) Inventors: Willy Rachmady, Beaverton, OR (US); Justin S. Sandford, Tigard, OR (US); Oleg Golonzka, Beaverton, OR (US)

Correspondence Address: INTEL CORPORATION;c/o CPA Global, P.O. BOX 52050, MINNEAPOLIS, MN, 55402, US

(21) Appl. No.: 11/965,317

(22) Filed: Dec. 27, 2007

(51) Int. Cl. H01L 21/311; H01L 23/29

(52) U.S. Cl. 257/788; 438/694; 257/E23.117; 257/E21.249

(57) ABSTRACT

In some embodiments an etchstop layer is deposited over a transistor that has been encapsulated by a high-K film, a silicon nitride is deposited over the deposited etchstop layer, the silicon nitride is removed, and the etchstop layer is removed. Other embodiments are described and claimed.

### TECHNICAL FIELD

The inventions generally relate to integrating a high stress cap layer in a high-K metal gate transistor.

### BACKGROUND

A transistor structure may be produced by encapsulating a silicon body and poly metal gate structure using a high-K (hi-K) layer. A silicon nitride film is then deposited over the hi-K layer. The silicon nitride (SiN) film is subsequently removed, but surface damage to the silicon, a loss of a poly hardmask (HM), and pitting on the hi-K liner can occur due to the removal of the silicon nitride (SiN) layer. Therefore, a need has arisen for a hi-K metal gate transistor structure without these problems occurring after a silicon nitride (SiN) layer is removed.

### BRIEF DESCRIPTION OF THE DRAWINGS

The inventions will be understood more fully from the detailed description given below and from the accompanying drawings of some embodiments of the inventions which, however, should not be taken to limit the inventions to the specific embodiments described, but are for explanation and understanding only.

FIG. 1 illustrates a process according to some embodiments of the inventions.

### DETAILED DESCRIPTION

Some embodiments of the inventions relate to integrating a high stress cap layer in a high-K metal gate transistor.

In some embodiments an etchstop layer is deposited over a transistor that has been encapsulated by a high-K film, a silicon nitride is deposited over the deposited etchstop layer, the silicon nitride is removed, and the etchstop layer is removed.

In some embodiments a high-K thin dielectric layer containing tantalum encapsulates a transistor.

In some embodiments a product is made by depositing an etchstop layer over a transistor that has been encapsulated by a high-K film, depositing a silicon nitride over the deposited etchstop layer, removing the silicon nitride, and removing the etchstop layer.

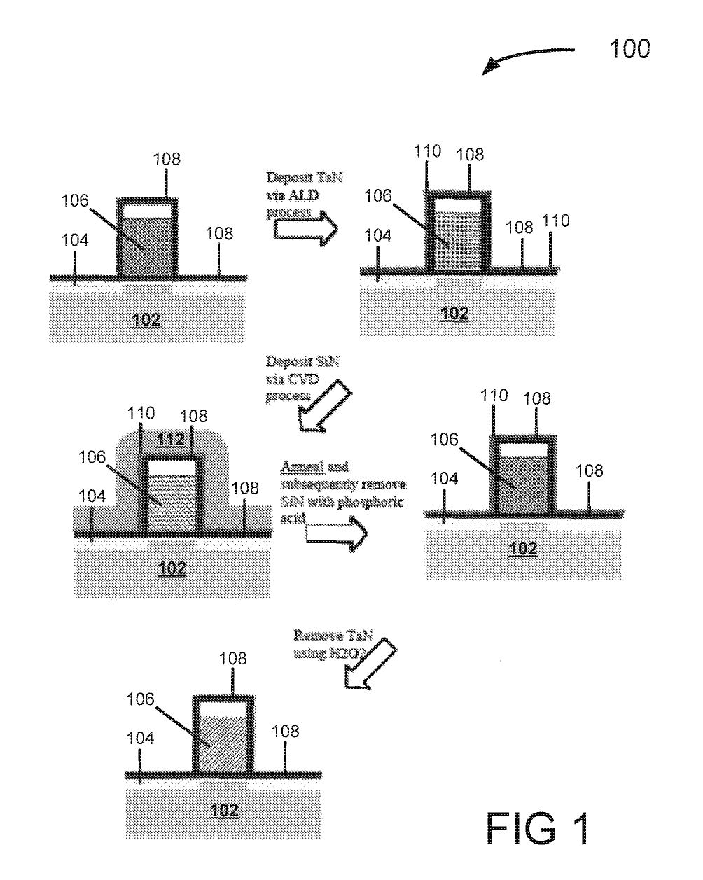

FIG. 1 illustrates a process 100 according to some embodiments. In some embodiments a semiconductor product is made according to process 100. In some embodiments, process 100 begins with a transistor structure including a silicon body 102, implanted tip regions 104, a poly metal gate 106 and a high-K (hi-K) layer (or liner) 108. The transistor structure has gate and source/drain bodies that have already been encapsulated, for example, by the high-K film liner 108. A few mono-atomic etchstop layer 110 of, for example, 5-15 A (5-15 Angstroms) of tantalum-nitride (TaN) film is deposited via an atomic layer deposition (ALD) process. A high stress silicon nitride or SiN film (for example, an Si₃N₄ film) 112 is then deposited via a process at which thickness and stress characteristics are well controlled (for example, in some embodiments via chemical vapor deposition or CVD). The structure is then subjected to a rapid high temperature anneal to “fix” the strain in the channel. The silicon nitride cap layer 112 is subsequently removed, for example, with phosphoric acid or an HF-based etchant (hydroflourocarbon-based etchant) which stops on the TaN layer 110. The presence of the TaN layer 110 protects the hi-K liner 108 and the poly hardmask (HM) of the poly metal gate 106 since both hi-K and poly hardmask are also susceptible to etching by phosphoric acid and HF (hydroflourocarbon) chemistry. The TaN etchstop layer 110 is subsequently removed using a hydrogen peroxide solution (H₂O₂) that is selective to hi-K.

In some embodiments, uniaxial strain is introduced in a hi-K/metal gate (MG) transistor channel by applying a sacrificial high stress film in a semiconductor process flow that integrates such a film (for example, etchstop layer 110). According to some embodiments, strain is introduced to the channel by annealing the gate and transistor body capped with a tensile silicon nitride (SiN) film (for example, in an NMOS process) after source/drain extensions or tips (for example, implanted tip regions 104) are formed. In some embodiments dislocation in the silicon creates strain in the channel. In some embodiments, an increase in drive current of the transistor structure is provided (for example, in some embodiments as measured by the inventors, an 11% increase in the drive current is possible).

In some embodiments, a cap layer is integrated into a device structure having a hi-K liner. A thin etchstop layer (for example, of tantalum-nitride or TaN) is inserted between a hi-K film (layer) and a silicon nitride (SiN) film (layer). The thin etchstop layer protects the hi-K layer from wet etchant that is applied to remove the silicon nitride (SiN).

In some embodiments a semiconductor such as a transistor is made with a process that includes a hi-K/metal gate transistor with a strained channel, a sacrificial high stress SiN film encapsulating the gate and transistor body, a thin metal etchstop layer sandwiched between the hi-K liner and the high stress SiN films. A wetetch process is used to remove the SiN that is selective to the TaN etchstop layer, and a selective wetetch process is then used to remove the TaN etchstop layer.

In some embodiments, device performance is improved via drive current enhancement without disruptively changing the transistor architecture.

In some embodiments, since both the TaN etchstop layer and the high stress SiN film are highly conformal, the process can be applied to both planar and/or non-planar devices.

In some embodiments, complete removal of the SiN cap is achieved without distortion to the gate profile of the transistor.

In some embodiments, a device gate structure has a thin dielectric encapsulating liner containing tantalum, and a strain exists in the channel layers. In some embodiments, dislocations also are present in the transistor (for example, an NMOS transistor).

Although some embodiments have been described herein as being performed in particular manner, according to some embodiments these particular implementations may not be required.

Although some embodiments have been described in reference to particular implementations, other implementations are possible according to some embodiments. Additionally, the arrangement and/or order of circuit elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

Some embodiments may be implemented in one or a combination of hardware, firmware, and software. Some embodiments may also be implemented as instructions stored on a machine-readable medium, which may be read and executed by a computing platform to perform the operations described herein. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other form of propagated signals (e.g., carrier waves, infrared signals, digital signals, the interfaces that transmit and/or receive signals, etc.), and others.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Although flow diagrams and/or state diagrams may have been used herein to describe embodiments, the inventions are not limited to those diagrams or to corresponding descriptions herein. For example, flow need not move through each illustrated box or state or in exactly the same order as illustrated and described herein.

The inventions are not restricted to the particular details listed herein. Indeed, those skilled in the art having the benefit of this disclosure will appreciate that many other variations from the foregoing description and drawings may be made within the scope of the present inventions. Accordingly, it is the following claims including any amendments thereto that define the scope of the inventions.

1. A method comprising:
depositing a thin metal etchstop layer over a high-K metal gate transistor with a strained channel, wherein the transistor has been encapsulated by a high-K film;
depositing a high stress silicon nitride film encapsulating the gate and transistor body over the deposited etchstop layer, wherein the thin metal etchstop layer is sandwiched between the high-K film and the high stress silicon nitride film;
removing the silicon nitride using a wetetch process that is selective to the etchstop layer; and
removing the etchstop layer using a selective wetetch process.

2. (canceled)

3. The method of claim 1, wherein the etchstop layer is a tantalum-nitride layer.

4. The method of claim 1, wherein the removing the silicon nitride stops on the etchstop layer.

5. The method of claim 1, wherein the removing the silicon nitride includes using phosphoric acid.

6. The method of claim 1, wherein the removing the silicon nitride includes using HF-based etchant.

7. The method of claim 1, wherein the removing the etchstop layer includes using hydrogen peroxide solution that is selective to high-K.

8. The method of claim 1, wherein the depositing of the etchstop layer is via atomic layer deposition.

9. The method of claim 1, further comprising after depositing the silicon nitride over the deposited etchstop layer and before removing the silicon nitride, subjecting the structure to a rapid high temperature anneal.

10. (canceled)

11. (canceled)

12. A product made by the process:
depositing an a thin metal etchstop layer over a high-K metal gate transistor with a strained channel, wherein the transistor that has been encapsulated by a high-K film;
depositing a high stress silicon nitride film encapsulating the gate and transistor body over the deposited etchstop layer, wherein the thin metal etchstop layer is sandwiched between the high-K film and the high stress silicon nitride film;
removing the silicon nitride using a wetetch process that is selective to the etchstop layer; and
removing the etchstop layer using a selective wetetch process.

13. (canceled)

14. The product of claim 12, wherein the etchstop layer is a tantalum-nitride layer.

15. The product of claim 12, wherein the removing the silicon nitride stops on the etchstop layer.

16. The product of claim 12, wherein the removing the silicon nitride includes using phosphoric acid.

17. The product of claim 12, wherein the removing the silicon nitride includes using HF-based etchant.

18. The product of claim 12, wherein the removing the etchstop layer includes using hydrogen peroxide solution that is selective to high-K.

19. The product of claim 12, wherein the depositing of the etchstop layer is via atomic layer deposition.

20. The product of claim 12, the process further comprising after depositing the silicon nitride over the deposited etchstop layer and before removing the silicon nitride, subjecting the structure to a rapid high temperature anneal.

21. The method of claim 1, further comprising introducing uniaxial strain in the high-K metal gate transistor channel by applying a sacrificial high stress film in the semiconductor process flow that integrates the film.

22. The method of claim 1, further comprising:
forming source/drain extensions or tips; and
introducing strain to the channel by annealing the gate and transistor body capped with a the silicon nitride film.

23. The product of claim 12, wherein the process further includes introducing uniaxial strain in the high-K metal gate transistor channel by applying a sacrificial high stress film in the semiconductor process flow that integrates the film.

24. The product of claim 12, the process further comprising:
forming source/drain extensions or tips; and
introducing strain to the channel by annealing the gate and transistor body capped with a the silicon nitride film.
